(19) United States
(12) Patent Application Publication
(10) Pub. No.: US 2023/0070377 A1
(43) Pub. Date: Mar. 9, 2023

(54) INTEGRATED STRUCTURE OF CIRCUIT MOLD UNIT OF LTCC ELECTRONIC DEVICE

(71) Applicant: Chun-Hsia Chen, Taoyuan City (TW)

(72) Inventor: Chun-Hsia Chen, Taoyuan City (TW)

(73) Assignee: ONANO INDUSTRIAL CORP., Taoyuan City (TW)

(21) Appl. No.: 17/471,053

(22) Filed: Sep. 9, 2021

(51) Int. Cl. H05K 1/02

(52) U.S. Cl. CPC H05K 1/0298; H05K 1/09

(57) ABSTRACT

An LTCC integrated circuit mold unit includes an integrated mold formed by multiple circuit mold units which are superposed, electrodes sheathed in the integrated mold and conductive wire sections sheathed in the integrated mold. Each circuit mold unit is formed by a ceramic base with an electrode pattern recess and a through hole. A denting depth of the electrode pattern recess is between 0.5 μm and 5000 μm. The through hole penetrates through the ceramic base. An inner diameter of the through hole is above 10 μm. The electrode pattern recess is filled with a conductive material to form one of the electrodes. Each through hole is filled with the conductive material to form one of the conductive wire sections. The conductive wire sections which are vertically adjacent are connected to form a conductive path. The conductive path electrically connects to at least one of the electrodes.

### BACKGROUND

### Technical Field

The invention relates to electronic devices made by the LTCC (low temperature co-fired ceramic technique) means.

### Related Art

The low temperature co-fired ceramic technique (LTCC) has been widely applied to portable products that emphasize compactness and is a technologic trend of wireless communication modules. The LTCC process embeds various passive devices, such as low-capacitance capacitors, resistors, filters, impedance converter, couplers, etc., into a multi-layer ceramic substrate and uses the printing-coating process to sinter to form an integrated ceramic part. As shown in FIG. 10, when a current LTCC technique is used to produce an electronic device, in the screen printing process, conductive glue is printed on a ceramic green embryo 800 to form a required electrode pattern 900, and solidified electrodes will be obtained after baking. A thickness of the electrodes formed by such a printing/coating manner can usually reach only about 10 μm. For those high power passive devices such as couplers, whose electrode thickness must reach 40 μm or more, it cannot be done by the abovementioned process. Multiple printing and baking can be adopted to form an electrode pattern with a required thickness, but the electrode patter may have outward expansion and burrs. This will reduce the performance of the product of the electronic device or cause deformation or the electrode pattern or hollows of edges of the electrodes when the overlapping step of the LTCC process is implementing.

To solve the above problem, the applicant provided an improved LTCC electronic device unit structure before. The structure selects a template layer whose thickness is the same as or slightly greater than a desired electrode thickness, the template layer is cut to form a required electrode pattern, and a conductive material is filled in the electrode pattern to obtain an electrode pattern with the required electrode thickness. This solution can be used to manufacture a high-power electronic device with a more electrode thickness. However, a multi-layer electrode structure and conductive connection between multi-layer electrodes were not disclosed. Thus, it cannot be applied to more and more complicated LTCC electronic devices.

### SUMMARY

An object of the invention is to provide an integrated structure of circuit mold unit of LTCC electronic device, which has a multi-layer electrode structure.

The multi-layer electrodes are electrically connected to form an integrated 3-diemnsional circuit structure.

To accomplish the above object, the invention provides an integrated structure of circuit mold unit of LTCC electronic device, which includes an integrated mold formed by multiple circuit mold units which are superposed, electrodes sheathed in the integrated mold and conductive wire sections sheathed in the integrated mold. Each circuit mold unit is formed by a ceramic base with an electrode pattern recess and a through hole. A denting depth of the electrode pattern recess is between 0.5 μm and 5000 μm. The through hole penetrates through the ceramic base. An inner diameter of the through hole is above 10 μm. The electrode pattern recess is filled with a conductive material to form one of the electrodes. Each through hole is filled with the conductive material to form one of the conductive wire sections. The conductive wire sections which are vertically adjacent are connected to form a conductive path. The conductive path electrically connects to at least one of the electrodes.

In an embodiment, the ceramic base is made of single-layer ceramic material, and a thickness of the ceramic base is below 5000 μm.

In an embodiment, the ceramic base is composed of two layers of ceramic material, the ceramic base comprises a template layer and a substrate layer, the substrate layer is superposed under the template layer, the template layer is formed with a hollow hole, the hollow hole and an upper surface of the substrate layer jointly form the electrode pattern recess, the through hole is formed in the template layer and the substrate layer in line, a thickness of the template layer if between 0.5 μm and 2000 μm, and a thickness of the substrate layer is above 10 μm.

In an embodiment, the integrated mole comprises a bottom circuit mold unit, the bottom circuit mold unit is superposed at a downmost side of the integrated mold, the bottom circuit mold unit is formed by a ceramic base with the electrode pattern recess, a denting depth of the bottom circuit mold unit is between 0.5 μm and 5000 μm, and the electrode pattern recess is filled with the conductive material to form one of the electrodes.

In an embodiment, each of two openings of the through hole is an opening with an expanded diameter.

### BRIEF DESCRIPTION OD THE DRAWINGS

FIG. 1 is a cross-sectional view of the invention;

FIG. 2 is a cross-sectional view of the integrated mold of the invention;

FIG. 3 is an explode view of the integrated mold of the invention;

FIG. 4 is a cross-sectional view of the first circuit mold unit of the invention, which shows the ceramic base and the conductive material filled therein;

FIG. 5 is a cross-sectional view of the second circuit mold unit of the invention, which shows the ceramic base and the conductive material filled therein;

FIG. 6 is a cross-sectional view of the third circuit mold unit of the invention, which shows the ceramic base and the conductive material filled therein;

FIG. 7 is a cross-sectional view of the bottom circuit mold unit of the invention, which shows the ceramic base and the conductive material filled therein;

FIG. 8 is a schematic view of another through hole of the invention, which shows the through hole with a flared opening;

FIG. 9 is a schematic view of still another through hole of the invention, which shows the through hole with a dumbbell-head-shaped opening; and

FIG. 10 is a cross-sectional view of a unit structure of an electronic device made by a conventional LTCC means.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

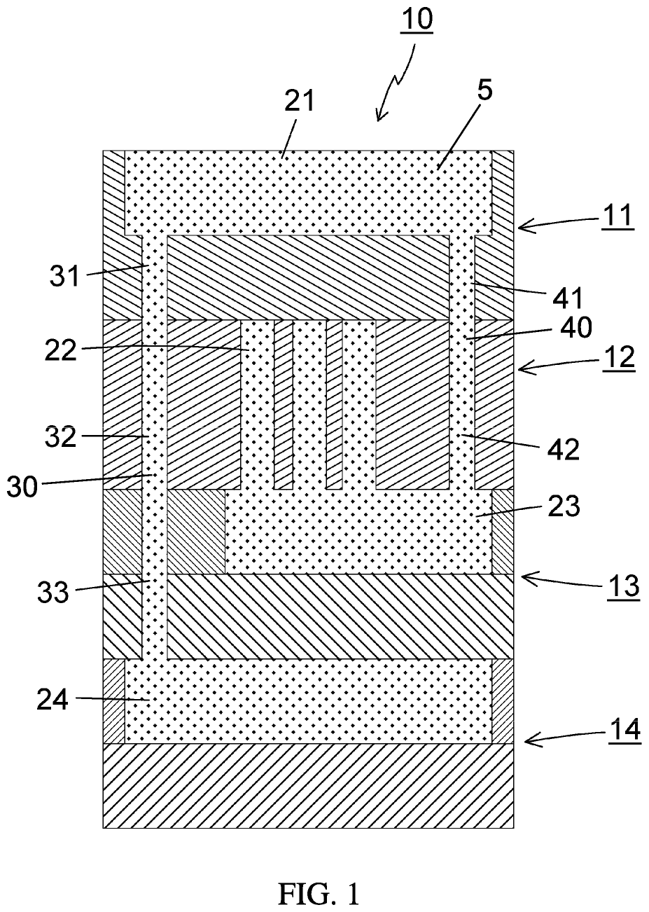

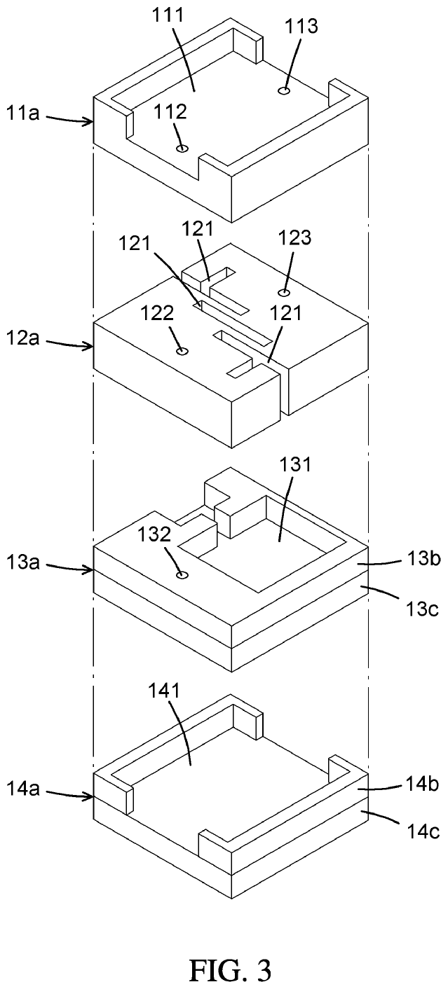

Please refer to FIGS. 1-3, which show an integrated structure of circuit mold unit of LTCC electronic device of the invention, which has four electrode layers. The invention includes an integrated mold 10, multiple electrodes 21-24 and multiple conductive wire sections 31, 32, 33, 41, 42. The electrodes 21-24 and the conductive wire sections 31, 32, 33, 41, 42 are sheathed in the integrated mold 10. The integrated mold 10 is composed of a first circuit mold unit 11, a second circuit mold unit 12, a third circuit mold unit 13 and a bottom circuit mold unit 14, which are superposed. Each circuit mold unit 11-14 is formed by a ceramic base 11a, 12a, 13a, 14a with a low dielectric constant and low dielectric loss. A single-layer or multi-layer ceramic base may be freely adopted. For example, in the embodiment, both the first circuit mold unit 11 and the second circuit module unit 12 adopt a single-layer ceramic base 11a, 12a, and both the third circuit mold unit 13 and the fourth circuit module unit 14 adopt a double-layer ceramic base 13a, 14a.

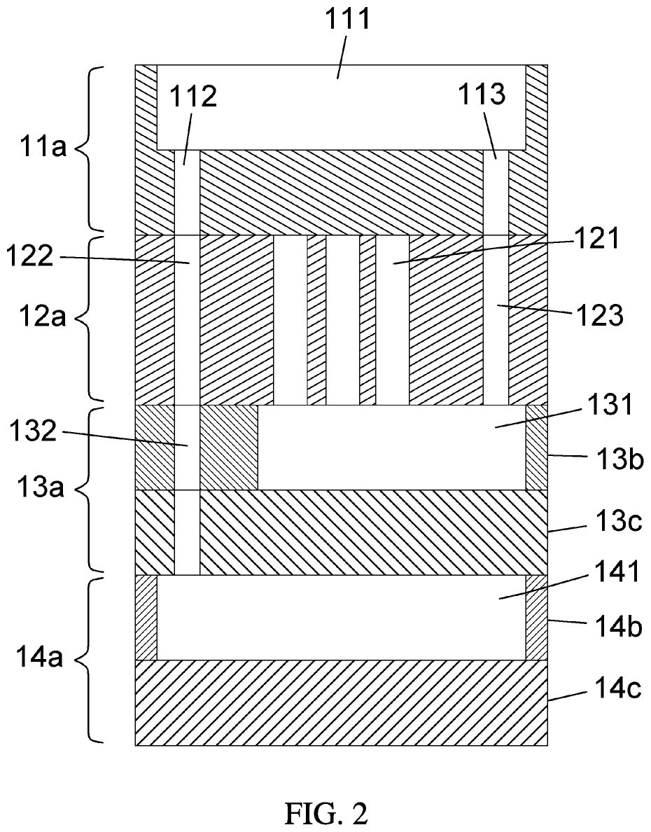

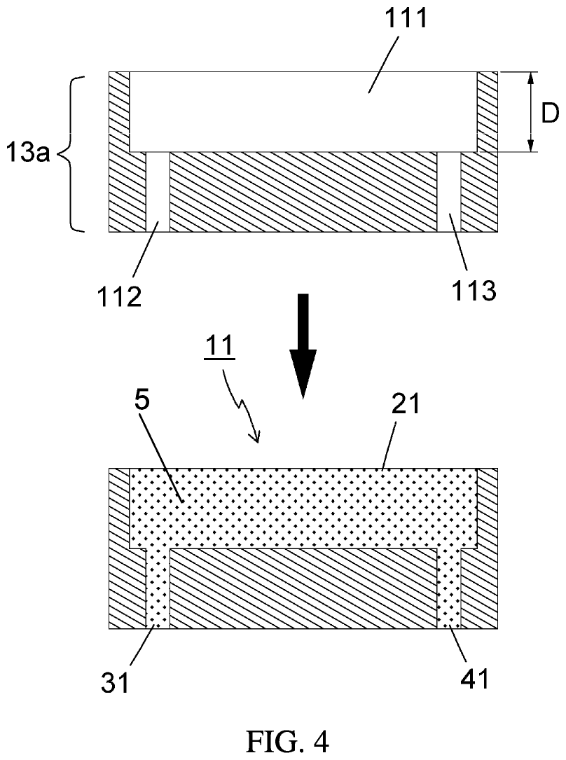

Please refer to FIGS. 2-4. A depth of the single-layer ceramic base 11a of the first circuit mold unit 11 is about 70 μm. A cutting device (such as a die machine) is used to form an electrode pattern recess 111 and two through holes 112, 113. A denting depth of the electrode pattern recess 111 is between 0.5 μm and 5000 μm, preferably about 40 μm. The through holes 112, 113 penetrate through the ceramic base 11a. An inner diameter of the through hole 112 or 113 is above 10 μm. The inner diameter of each through hole 112, 113 should be large enough to guarantee great electric conductivity of the through holes 112, 113 after they are filled with conductive material 5. The electrode pattern recess 111 is filled with a conductive material 5 to form the first electrode 21. Each through hole 112, 113 is filled with the conductive material 5 to form one of the conductive wire sections 31, 41. The electrode 21 and the conductive wire sections 31, 41 are formed by filling liquid conductive material 5 such as conductive glue with silver (Ag) content of more than 80% in the electrode pattern recess 111 and the through holes 112, 113 and then heating and drying the conductive material 5 to form the electrode 21 and the conductive wire sections 31, 41 embedded and fixed in the ceramic base 11a.

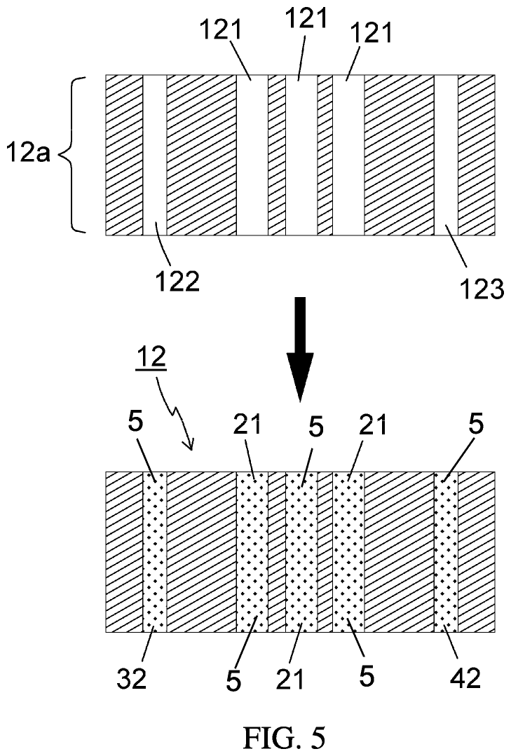

Please refer to FIGS. 2, 3 and 5. A depth of the single-layer ceramic base 12a of the second circuit mold unit 12 is about 70 μm. A cutting device is used to form multiple electrode pattern recesses 121 and two through holes 122, 123. The electrode pattern recesses 121 and the through holes 122, 123 penetrate through the ceramic base 12a. An inner diameter of the through hole 122 or 123 is above 10 μm. The electrode pattern recesses 121 are filled with the conductive material 5 to form the second electrodes 22. Each through hole 122, 123 is filled with the conductive material 5 to form one of the conductive wire sections 32, 42.

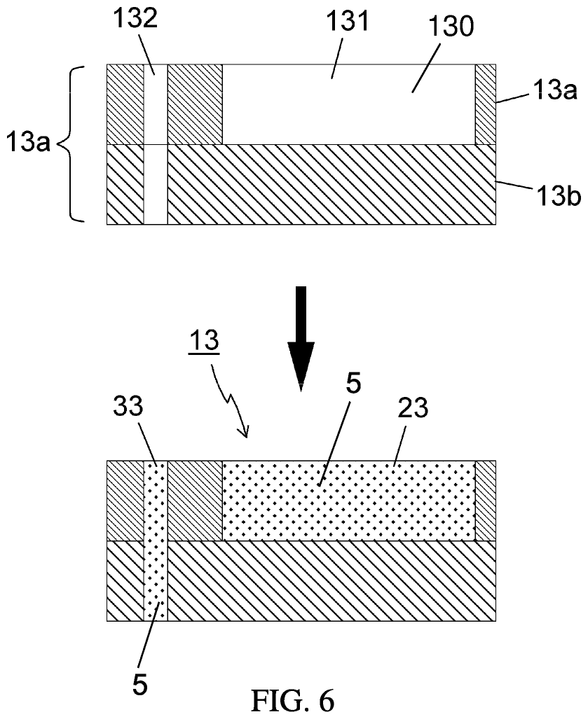

Please refer to FIGS. 2, 3 and 6. The double-layer ceramic base 13a of the third circuit mold unit 13 is composed of a template layer 13b and a substrate layer 13c. The substrate layer 13c is superposed under the template layer 13b. The template layer 13b adopts a ceramic green embryo with a thickness of about 40 μm. A cutting device is used to form a hollow hole 130 in the template layer 13b. The hollow hole 130 and an upper surface of the substrate layer 13b jointly form an electrode pattern recesses 131. The substrate layer 13b is used to limit and support the conductive material 5 filled in the electrode pattern recess 131, so a thickness of the substrate layer 13b is preferably above 10 μm to guarantee the structural strength of the electrode pattern recess 131. A through hole 132 is formed in the template layer 13a and the substrate layer 13b in line. An inner diameter of the through hole 132 is above 10 μm. The electrode pattern recess 131 is filled with the conductive material 5 to form the third electrodes 23. The through hole 132 is filled with the conductive material 5 to form the conductive wire section 33.

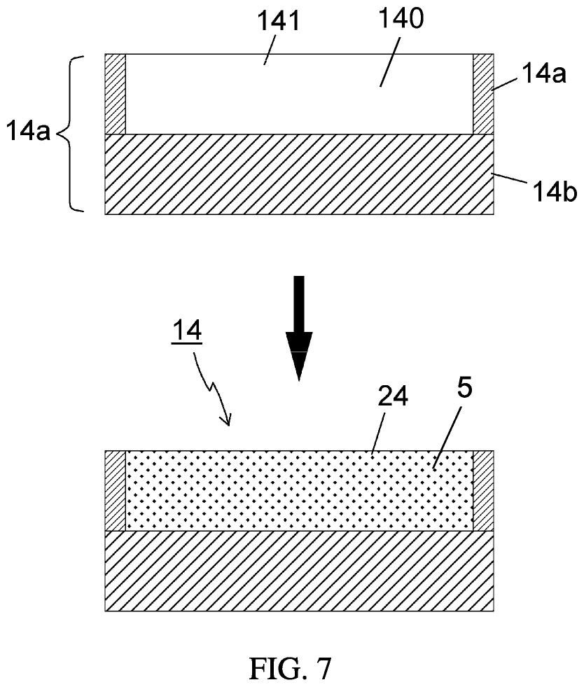

Please refer to FIGS. 2, 3 and 7. The double-layer ceramic base 14a of the bottom circuit mold unit 14 is composed of a template layer 14b and a substrate layer 14c. The substrate layer 14c is superposed under the template layer 14b. The template layer 14b adopts a ceramic green embryo with a thickness of about 40 μm. A cutting device is used to form a hollow hole 140 in the template layer 14b. The hollow hole 140 and an upper surface of the substrate layer 14b jointly form an electrode pattern recesses 141. The electrode pattern recesses 141 is filled with the conductive material 5 to form the fourth electrodes 24.

The first circuit mold unit 11, the second circuit mold unit 12, the third circuit mold unit 13 and the bottom circuit mold unit 14 are stacked, laminated, burned-out and sintered in order to make the conductive wire sections 31, 32, 33, 41, 42 which are vertically adjacent are electrically connected to form a conductive path 30, 40. The conductive paths 30, 40 electrically connects to the electrodes 21-24 in the integrated mold 10 to form an integrated s-dimensional circuit structure. As shown in FIG. 1, in the embodiment, the conductive wire sections 31, 32, 33 electrically connect the first electrode 21 to the fourth electrode 24, the conductive wire sections 41, 42 electrically connect the first electrode 21 to the third electrode 23, and the second electrode 22 directly connects to the third electrode 23.

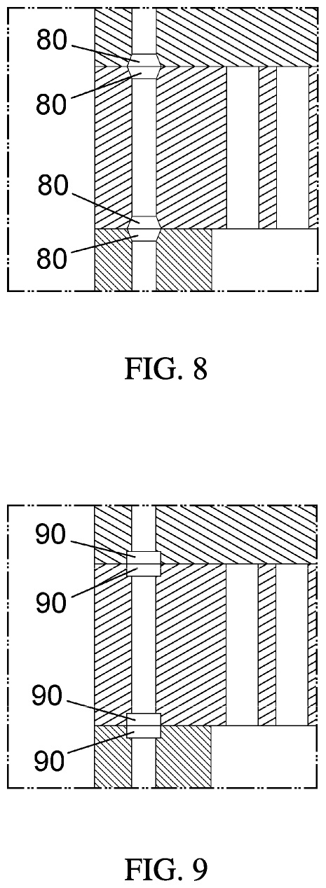

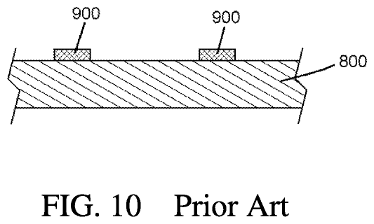

The above embodiment discloses a structural arrangement of multiple typical circuit mold units. For the ceramic base, in addition to single-layer or multi-layer options, its depth is not limited, and both the electrode pattern recess and the though hole may be multiple in number. In addition, the through holes of the ceramic bases are straight holes, but if you consider the operation of facilitating the filling of conductive material into the hole, two openings of the through hole may also be shaped with an expanded diameter, such as a flared opening 80 as shown in FIG. 8 or a dumbbell-head-shaped opening 90 as shown in FIG. 9, but not limited to these. On the other hand, the expanded openings are advantageous to the electric connection between the conductive wire sections 31, 32, 33, 41, 42.

While this disclosure has been described by means of specific embodiments, numerous modifications and variations could be made thereto by those skilled in the art without departing from the scope and spirit of this disclosure set forth in the claims

What is claimed is:

1. An integrated structure of circuit mold unit of LTCC (low temperature co-fired ceramic technique) electronic device, comprising:
an integrated mold, formed by multiple circuit mold units which are superposed;
electrodes, sheathed in the integrated mold; and
conductive wire sections, sheathed in the integrated mold;
wherein each circuit mold unit is formed by a ceramic base with an electrode pattern recess and a through hole, a denting depth of the electrode pattern recess is between 0.5 μm and 5000 μm, the through hole penetrates through the ceramic base, an inner diameter of the through hole is above 10 μm, the electrode pattern recess is filled with a conductive material to form one of the electrodes, each through hole is filled with the conductive material to form one of the conductive wire sections, the conductive wire sections which are vertically adjacent are connected to form a conductive path, and the conductive path electrically connects to at least one of the electrodes.

2. The integrated structure of circuit mold unit of LTCC electronic device of claim 1, wherein the conductive material contains conductive metal, and the conductive metal selects from one or more of gold, silver and an alloy thereof.

3. The integrated structure of circuit mold unit of LTCC electronic device of claim 2, wherein the conductive material is conductive glue containing more than 80% silver by weight.

4. The integrated structure of circuit mold unit of LTCC electronic device of claim 1, wherein the ceramic base is made of single-layer ceramic material, and a thickness of the ceramic base is below 5000 μm.

5. The integrated structure of circuit mold unit of LTCC electronic device of claim 1, wherein the ceramic base is composed of two layers of ceramic material, the ceramic base comprises a template layer and a substrate layer, the substrate layer is superposed under the template layer, the template layer is formed with a hollow hole, the hollow hole and an upper surface of the substrate layer jointly form the electrode pattern recess, and the through hole is formed in the template layer and the substrate layer in line.

6. The integrated structure of circuit mold unit of LTCC electronic device of claim 5, wherein a thickness of the template layer if between 0.5 μm and 2000 μm.

7. The integrated structure of circuit mold unit of LTCC electronic device of claim 5, wherein a thickness of the substrate layer is above 10 μm.

8. The integrated structure of circuit mold unit of LTCC electronic device of claim 1, wherein the integrated mole comprises a bottom circuit mold unit, the bottom circuit mold unit is superposed at a downmost side of the integrated mold, the bottom circuit mold unit is formed by a ceramic base with the electrode pattern recess, a denting depth of the bottom circuit mold unit is between 0.5 μm and 5000 μm, and the electrode pattern recess is filled with the conductive material to form one of the electrodes.

9. The integrated structure of circuit mold unit of LTCC electronic device of claim 1, wherein each of two openings of the through hole is an opening with an expanded diameter.
